(19) United States
(12) Patent Application Publication
(10) Pub. No.: US 2026/0191035 A1
(43) Pub. Date: Jul. 2, 2026

(54) ORGANIC INTERPOSER WITH FANOUT ROUTING DIE

(71) Applicants: Bernd Waidhas, Pettendorf (DE); Kavitha Nagarajan, Bangalore KA (IN); Abdallah Bacha, Munich (DE); Mohan Prashanth Javare Gowda, Ottobrunn (DE); Klaus Heinz Goebel, Taipei (TW); Han-Wen Lin, Zhubei City (TW); Chee Kheong Yoon, Beyan Lepas (MY); Eng Huat Goh, Penang (MY); Jooi Wah Wong, Bukit Mertajam (MY); Jiun Hann Sir, Penang (MY); Chu Aun Lim, Hillsboro, OR (US)

(72) Inventors: Bernd Waidhas, Pettendorf (DE); Kavitha Nagarajan, Bangalore KA (IN); Abdallah Bacha, Munich (DE); Mohan Prashanth Javare Gowda, Ottobrunn (DE); Klaus Heinz Goebel, Taipei (TW); Han-Wen Lin, Zhubei City (TW); Chee Kheong Yoon, Beyan Lepas (MY); Eng Huat Goh, Penang (MY); Jooi Wah Wong, Bukit Mertajam (MY); Jiun Hann Sir, Penang (MY); Chu Aun Lim, Hillsboro, OR (US)

(21) Appl. No.: 19/002,051

(22) Filed: Dec. 26, 2024

(51) Int. Cl. H01L 23/538; H01L 23/00; H01L 23/498; H01L 25/18; H10B 80/00; H10D 80/20

(52) U.S. Cl. CPC H10W 70/611; H10W 70/65; H10W 70/685; H10W 90/00; H10W 90/401; H10B 80/00; H10D 80/251; H10W 70/655; H10W 90/724

(57) ABSTRACT

Microelectronic assemblies with organic interposers and fanout routing dies are described. In one example, an assembly includes an interposer with one or more redistribution layers (RDLs) and first conductive contacts with a first pitch on a first side of the interposer, and a die (e.g., fanout routing die) with two or more backend of line (BEOL) interconnect layers. The assembly may further include second conductive contacts with the first pitch coupled with the first conductive contacts, and third conductive contacts with a second pitch that is smaller than the first pitch, where one of the third conductive contacts is coupled with a conductive interconnect in the RDLs of the interposer.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A illustrates a top down view of an example of a microelectronic assembly including an organic interposer in which a fanout routing die may be included, according to some embodiments of the present disclosure.

FIG. 1B illustrates a cross-sectional side view of an example of the microelectronic assembly of FIG. 1A, according to some embodiments of the present disclosure.

FIG. 1C is a diagram of a die that may be included in an assembly that includes an organic interposer with a fanout routing die, in accordance with embodiments.

FIGS. 2-4 illustrate cross-sectional side view of examples of microelectronic assemblies including an organic interposer with a fanout routing die, according to some embodiments of the present disclosure.

FIGS. 5A-5D illustrate cross-sectional side views of examples of fanout routing dies, according to some embodiments of the present disclosure.

FIG. 6 is a top view of a wafer and dies that may be included in any microelectronic assembly disclosed herein, in accordance with any of the embodiments disclosed herein.

FIG. 7 is a side, cross-sectional view of an IC package that may include, or be included in, any microelectronic assembly disclosed herein, in accordance with various embodiments.

FIG. 8 is a side, cross-sectional view of an IC device assembly that may include or be an example of a microelectronic assembly disclosed herein, in accordance with any of the embodiments disclosed herein.

FIG. 9 is a block diagram of an example electrical device that may include, or be included in, any of the microelectronic assemblies disclosed herein, in accordance with any of the embodiments disclosed herein.

### DETAILED DESCRIPTION

Disclosed herein are microelectronic assemblies including an organic interposer with a fanout routing die, which may enable local high-density fanout routing on an organic interposer. The systems, methods, and devices of this disclosure each have several innovative aspects, no single one of which is solely responsible for all desirable attributes disclosed herein. Details of one or more implementations of the subject matter described in this specification are set forth in the description below and the accompanying drawings.

Semiconductor chip manufacturing involves a series of complex processes to create integrated circuit (IC) structures. These processes include photolithography, ion implantation, etching, and deposition. A wafer typically goes through multiple rounds of these processes to form devices and interconnects on the wafer. Once the wafer processing is complete, the wafer may be cut into individual chips (also called dies). After dicing, the individual dies are packaged to provide interconnections with other components and protection.

Packaging the dies may involve attaching the dies to a substrate (such as a motherboard, interposer, or other circuit board or structure with conductive interconnects) to connect the die's conductive contacts to the package's conductive contacts (e.g., with flip chip bonding, ball grid array (BGA), etc.). For attachment to a circuit board, a die may be soldered directly onto the board or inserted into a socket (e.g., in the case of a packaged die). In some cases, multiple dies may be combined (e.g., stacked) into a single assembly or package before being mounted on the circuit board.

Two dies or die stacks on a circuit board may communicate with one another through conductive interconnects in the circuit board and through pads and bumps at the interface between the circuit board and the dies or die stacks. Thus, conductive lines and vias in each of the dies or die stacks typically end on the bumps at the interface between the circuit board and the dies.

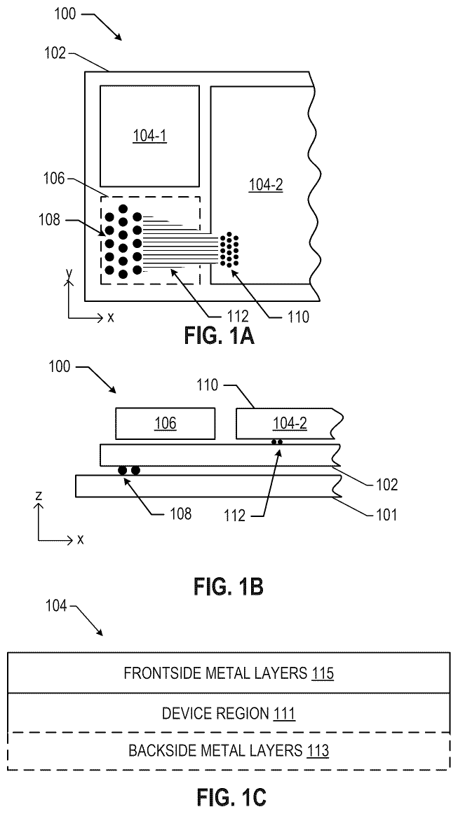

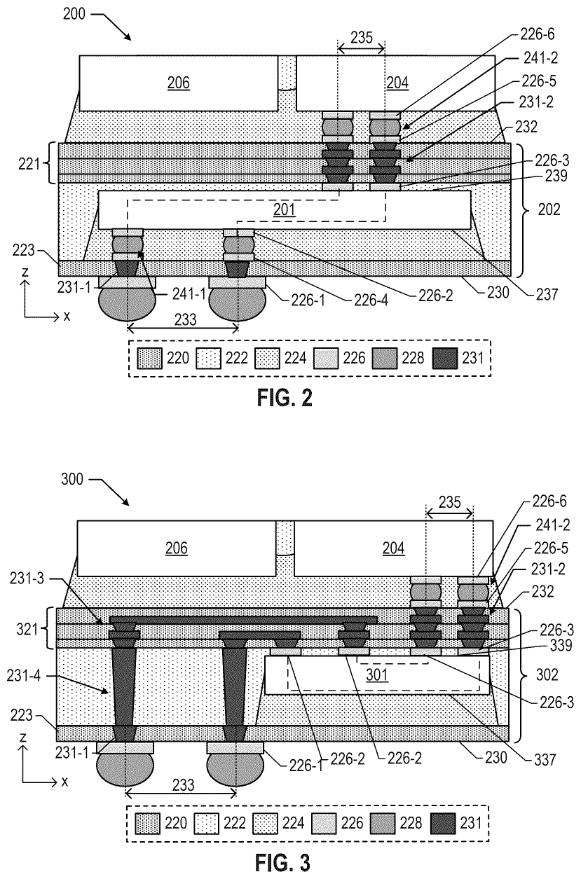

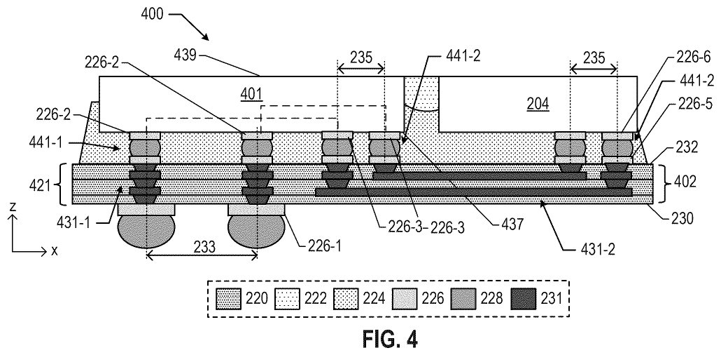

In some examples, multiple IC dies (e.g., chips or chiplets) may be attached to an interposer, which may be attached to a motherboard, package substrate, or other structure. Heterogeneous integration and reuse or IC dies, e.g., for different product families, may involve high-density routing from a die located near the center of the interposer to interposer bumps near the edge of the interposer, such as shown in FIGS. 1A-1B.

Turning first to FIG. 1A, FIG. 1A illustrates a top down view of a microelectronic assembly 100. The microelectronic assembly 100 includes IC dies 104-1 and 104-2 over and attached to an interposer 102. The microelectronic assembly 100 may also include one or more “dummy dies,” such as the dummy die 106. A dummy die may occupy area on the interposer 102 that is not occupied by an active die, such as the dies 104-1 and 104-2, to enable more uniform mechanical properties across the assembly 100. The interposer 102 is typically an intermediate structure in a microelectronic assembly that enables electrically coupling IC structures with one another and/or to the package substrate. For example, the interposer 102 facilitate coupling the dies 104-1 and 104-2 with a package substrate 101, as can be seen in the cross-sectional side view of FIG. 1B. The interposer 102 may be or include one or more layers of a dielectric material and conductive interconnects (e.g., conductive lines and vias) in the dielectric material. The dielectric material of the interposer 102 may include silicon (e.g., in the case of a silicon-based interposer), include an organic dielectric material (e.g., in the case of an organic interposer), or both a dielectric material that includes silicon and an organic dielectric. Examples of silicon-based dielectric materials that may be included in one or more layers of the interposer 102 include silicon and one or more of oxygen and nitrogen (e.g., silicon oxide, silicon nitride, or silicon oxynitride). Examples of organic dielectric materials that may be included in one or more layers of the interposer 102 include a fire retardant grade 4 material (FR-4), bismaleimide triazine (BT) resin, polyimide materials, glass reinforced epoxy matrix materials, organic dielectrics with inorganic fillers (e.g., mold materials) or low-k and ultra low-k dielectric (e.g., carbon-doped dielectrics, fluorine-doped dielectrics, porous dielectrics, and organic polymeric dielectrics).

The dies 104-1 and 104-2 may be, for example, discrete IC structures, which may be referred to as chiplets, which may be packaged together. Often, different chiplets in an IC device or system may include logic to provide a particular functionality in the IC device or system. For example, an IC device may include one or more compute chiplets, memory chiplets, cache chiplets, accelerator chiplets, etc. The terms IC die, die, chiplet, chip, and microelectronic component may be used interchangeably. For example, a compute chiplet may also be referred to as a compute die. In one example, a compute chiplet may include one or more processor cores and/or other compute logic. In one example, a compute chiplet that includes one or more processor cores may be referred to as a processor chiplet or processor die. A memory chiplet may include one or more memory arrays (e.g., dynamic random access memory (DRAM) and/or static random access memory (SRAM) arrays). A cache chiplet may include one or more memory arrays (e.g., an SRAM array or other low latency memory). Chiplets may have more than one type of device, for example, a compute chiplet may also include one or more memory arrays, and a memory chiplet may include compute logic. The dies 104-1 and 104-2 may include a device region and one or more interconnect layers, such as shown in FIG. 1C.

FIG. 1C shows a diagram of a die 104 with a device region 111, frontside metal layers 115 over the device region, and backside metal layers 113. The device region includes devices formed over a substrate, and may include or be referred to as a front end of line (FEOL) layer. The device region 111 may include frontend devices (e.g., frontend transistors such as FinFETs, nanowire/nanoribbon transistors, frontend memory cells, or other frontend devices). The frontside metal layers 115 are over a front side of the device region, and the backside metal layers 113 are over a back side of the device region. The metal layers 115, 113 may also be referred to as back end of line (BEOL) layers. Various metal layers 115, 113 may be used to interconnect the various inputs and outputs of the devices (e.g., logic devices or memory devices) in the device regions 111. In one example, each of the metal layers may include vias and lines/trenches, as discussed in further detail below. The metal layers 115 and 113 may also include devices (e.g., backend devices). Some dies may include more, fewer, and or different layers/regions than shown in FIG. 1C. For example, some dies may have only a device region and frontside metal layers 115, but lack backside metal layers. Other dies may lack a device region (e.g., in the case of a passive interconnect die).

Referring again to FIG. 1A, the interposer 102 may include routing between the IC dies 104-1 and 104-2 and bumps 108 (e.g., bumps at the bottom of the interposer 102). High-density routing may be especially used for die-to-die interconnects and fanout routing, whereas lower density routing may be used for power supply. For example, the microelectronic assembly 100 may include high-density routing (as shown with the conductive interconnects 112) between bumps 110 (which have a relatively tight pitch) on the die 104-2 and bumps 108 (which may have a wider pitch) on the interposer 102. Such high-density routing may be implemented with silicon-based interposers, but can be problematic when using organic dielectric-based redistribution layer (RDL) interposer technology, which may be desirable to use in some products due to its relatively lower cost compared to silicon-based interposers. For example, silicon-based interposers may leverage the metal layer BEOL routing capabilities of wafer manufacturing, which may offer design rules down to very small line widths and spaces (e.g., submicron lines and spaces, as an example) and small via pads and vias (e.g., low single digit micron widths, as an example) between the metal routing layers. In contrast, organic interposers typically use coarser design rules, which may limit interconnect and pad widths (e.g., organic dielectric RDLs may have single digit micron lines and spaces and double digit micron via pads, as an example), which can make high-density routing a challenge.

Organic RDL interposers with silicon-based rerouting dies in areas with higher routing density can enable a relatively low cost solution (e.g., due to the use of an organic interposer) with the high-density routing capabilities of a silicon-based die. In one example, a microelectronic assembly includes an interposer with a first side and a second side opposite the first side, where the first side includes first conductive contacts (e.g., pads) with a first pitch, and an interconnect die (e.g., a fanout routing die) that includes two or more interconnect layers, second conductive contacts with the first pitch coupled with the first conductive contacts, and third conductive contacts with a second pitch that is smaller than the first pitch, where the third conductive contacts are coupled with an IC die coupled with the interposer (e.g., via conductive interconnects in RDLs of the interposer). In one example, the fanout routing die may be embedded in an organic interposer. In one example, in an organic interposer, a fanout routing die could be placed side-by side with a die having active devices for local improved routing capability. The metal layer stack and routing in the fanout die can be also used for signal trace shielding or impedance matching for improved signal integrity of the fanout routing. Some benefits of integrating a fanout routing die with an organic interposer may include the use of optimized interposer technology for cost sensitive products, signal integrity improvement by a local increase of layer count and/or denser design rules by coplanar or strip line routing, support of high bump density and low bump pitch routing, and reduced thermal resistance from a top die to a bottom interposer, which may enable a potential thermal dissipation path.

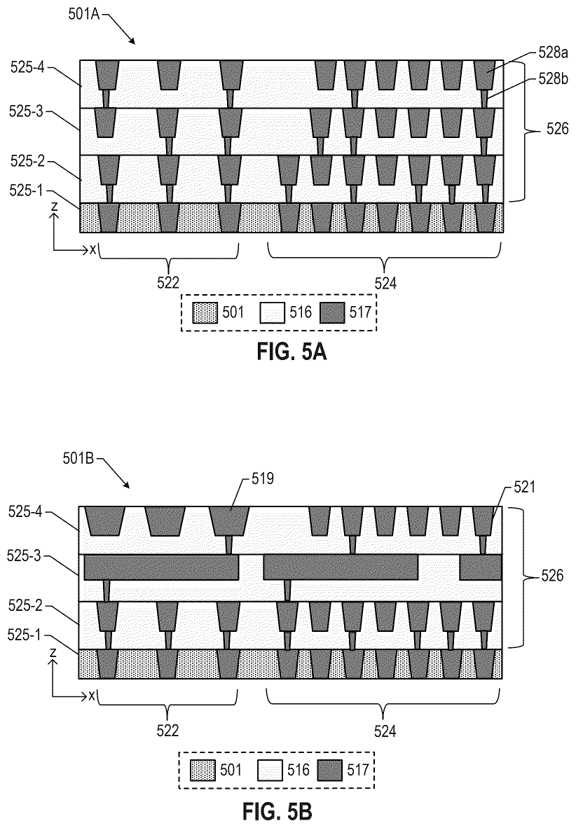

FIGS. 2-4 illustrate examples of different integration schemes of such fanout rerouting die assemblies. A number of elements referred to in the description of FIGS. 2-4 and 5A-5D with reference numerals are illustrated in these drawings with different patterns, with a legend showing the correspondence between the reference numerals and patterns being provided at the bottom of each drawing page containing FIGS. 2-4 and 5A-5D. For example, the legend illustrates that FIGS. 2-4 use different patterns to show a conductive bump 228 and a conductive pad 226, and so on.

FIG. 2 illustrates a cross-sectional side view of an example of a microelectronic assembly 200 including an organic interposer 202 with an embedded fanout routing die 201. The interposer includes layers of a dielectric material 220. In one example, the dielectric material 220 is an organic dielectric material. One or more of the layers of dielectric material 220 may be RDL layers. For example, the organic interposer 202 includes RDLs 221. Each of the RDLs 221 includes a plurality of conductive lines (e.g., redistribution lines) to form a conductive pathway through the interposer 202. For example, the RDLs 221 of FIG. 2 include conductive interconnects 231, which may include conductive lines and conductive vias. The RDLs 221 may be formed using various thin film and/or printed circuit board (PCB) deposition processes, including sputtering and plating, electroless seed layer application, electroplating, printing, and/or other deposition processes. In some examples, the RDLs 221 may be formed on a panel carrier by laminating or spinning on a dielectric material, and creating conductive vias and lines by laser drilling and plating. In some examples, the RDLs 221 may be formed using high-density fanout (HD-FO) deposition processes as used for wafer-level or fanout wafer-level packages. In one such example, dielectric deposition processes may include spin-on coating (e.g., for round wafers or carriers), spray coating, or screen printing (e.g., for rectangular panels). The conductive interconnects 231 in the RDLs 221 may include any suitable conductive material, including one or more of: copper, aluminum, gold, silver, tungsten, and/or another conductive material.

The interposer 202 has a first face or side 230 (e.g., bottom side) and a second face or side 232 (e.g., top side) that is opposite the first side 230. The first side 230 includes conductive contacts 226-1 with a first pitch 233 (where the pitch of contacts is a measurement of distance between an approximate center of a contact and an approximate center of an adjacent contact). As used herein, a “conductive contact” may refer to a portion of conductive material (e.g., metal) serving as an electrical interface between different components (e.g., part of a conductive interconnect); conductive contacts may be recessed in, flush with, or extending away (e.g., having a pillar shape) from a surface of a component, and may take any suitable form (e.g., a conductive pad or socket, or portion of a conductive line or via). In a general sense, an “interconnect” refers to any element that provides a physical connection between two other elements. For example, an electrical interconnect provides electrical connectivity between two electrical components, facilitating communication of electrical signals between them. Thus, when used with reference to an electronic device, such as an IC that operates using electrical signals, the term “interconnect” describes any element formed of a conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, conductive traces and vias may be referred to as “metal traces” and “metal vias”, respectively, to highlight the fact that these elements include conductive materials such as metals. In the example illustrated in FIG. 2, the conductive contacts 226-1 have a relatively large or wide pitch 233, and are coupled with corresponding conductive bumps 228. The second side 232 includes conductive contacts 226-5 with a second pitch 235. In the example illustrated in FIG. 2, the conductive contacts 226-5 have a relatively small or narrow pitch 235 that is smaller than the pitch 233, and are coupled with corresponding conductive bumps 228, conductive contacts 226-6 and an IC die 204. In one example, the bumps 228 at the bottom of the interposer 202, which are coupled with the conductive contacts 226-1, may be C4 bumps. In one such example, the pitch 233 of the conductive contacts 226-1 (and the pitch of the corresponding conductive bumps 228) may be in the range of about 100 to 200 microns, about 110 to 150 microns. In one example, the pitch 235 of the conductive contacts 226-5 (and the pitch of the corresponding conductive bumps 228) may be in a range of about 25 to 100 microns. Thus, in the example illustrated in FIG. 2, the first side 230 of the interposer 202 includes relatively large pitch contacts and bumps, and faces and couples with a package substrate (or other circuit board or structure). The second side 232 of the interposer 202 includes relatively tight pitch contacts and bumps, and faces and couples with one or more dies, such as the IC die 204.

The microelectronic assembly 200 includes an IC die 204 and a dummy die 206 over and bonded with the interposer 202. The IC die 204 may be an example of the IC dies 104, discussed above. In the example illustrated in FIG. 2, the microelectronic assembly 200 includes an underfill material 224 between the second side 232 of the interposer 202 and the IC die 204. In some examples, the underfill material 224 surrounds the conductive bumps 228 between the die 204 and the organic interposer 202 in a plane with the conductive bumps 228. The underfill material 224 may be provided according to any suitable method (e.g., deposited before or after formation of the bumps), and may provide mechanical support to an interface layer with conductive bumps 228. In some examples, the underfill material 224 may be any suitable insulator material. In some examples, the underfill material 224 includes an organic dielectric material, such as an organic polymer material. In some examples, the underfill material 224 may include inorganic filler materials, such as silicon oxide, silicon carbide, silicon oxynitride, carbon-doped silicon oxide, boron-doped silicon oxide, or any other suitable inorganic insulator material. A molding compound 222 may be between the IC die 204 and dummy die, and may further be over and/or around the IC die 204 and dummy die 206. The molding compound may be any material known to be suitable for over-molded IC packages, such as an epoxy resin, silicone, a composite thereof, or any other suitable molding material. The underfill material 224 and the molding compound 222 may include the same or different material compositions.

In the example illustrated in FIG. 2, the fanout routing die 201 is embedded in, and disposed between layers of the dielectric material 220 of the organic interposer 202. In the example illustrated in FIG. 2, the fanout routing die 201 is between the RDLs 221 and the conductive contacts 226-1 at the bottom of the interposer 202 (and therefore between the RDLs 221 and a bottom layer of the dielectric material 220 of the interposer 202). From another perspective, in the example illustrated in FIG. 2, the fanout routing die 201 is between the IC die 204 and the conductive contacts 226-1. In the example illustrated in FIG. 2, tighter pitch contacts are on the top side of the fanout routing die 201 and wider pitch contacts are on the bottom side of the fanout routing die. For example, the fanout routing die 201 has a first side 237 (e.g., bottom side that is closer to the conductive contacts 226-1) and a second side 239 (e.g., top side that is closer to the IC die 204 and further from the conductive contacts 226-1) opposite the first side 237. The first side 237 of the fanout routing die 201 is facing the bottom (e.g., the side 230) of the interposer 202, and the first side 237 of the interposer 202 includes the conductive contacts 226-2 with the wider pitch 233 and the second side 239 of the interposer 202 includes the conductive contacts 226-3 with the narrower pitch 235. An electrical path may be formed between the IC die 204 and the conductive contacts 226-1 at the bottom of the interposer via the fanout routing die 201. For example, referring FIG. 2, the assembly 200 includes a solder joint 241-1 between one of the conductive contacts 226-2 and one of the conductive contacts 226-4, a conductive via 231-1 in the RDL 223 between the conductive contact 226-4 and one of the conductive contacts 226-1, a solder joint 241-2 between one of the conductive contacts 226-6 and one of the conductive contacts 226-5, and one or more vias and/or lines (e.g., the conductive interconnects 231-2) in the RDLs 221. Thus, an electrical path may be formed from the conductive contacts 226-6, through the solder joint 241-2, the conductive contacts 226-5, the conductive interconnects 231-2, the conductive contacts 226-3, conductive interconnects in the fanout routing die 201, the conductive contacts 226-2, the solder joint 241-1, the conductive contacts 226-4, the via 231-1, and the conductive contacts 226-1.

In the example illustrated in FIG. 2, the underfill material 224 is present between the bottom (e.g., the side 237) of the fanout routing die 201 and the bottom (e.g., the side 230) of the interposer 202. In one example, conductive contacts 226-4 are present between the conductive contacts 226-1 at the bottom of the interposer 202 and the conductive contacts 226-2 at the bottom of the fanout routing die 201 (e.g., there are contacts that connect the fanout routing die with the pads at the bottom of the interposer). In one such example, the underfill material 224 is coplanar with the conductive contacts 226-2, 226-4, and the conductive bumps 228 between the conductive contacts 226-2 and the conductive contacts 226-4. For example, the underfill material 224 may surround the solder joint 241-1 (e.g., surround the conductive contacts 226-2, 226-4, and the conductive bumps 228 between the conductive contacts 226-2 and the conductive contacts 226-4 between the fanout routing die 201 and the bottom layer of dielectric material 220 of the interposer 202).

Thus, in the example illustrated in FIG. 2, IP blocks of the IC die 204 with high bump count and density may be coupled with a via stack (e.g., the conductive interconnects 231-2) through the RDLs 221 directly to the fanout routing die 201 (e.g., with stacked or staggered vias). In one such example, there is no RDL routing between the via pads (e.g., no routing in terms of metal lines other than lines present in the via stack) in the area with the high bump count and density. Instead, in one example, fanout routing is done in the BEOL layers of the embedded fanout routing die. For example, the fanout routing die 201 may include conductive vias and lines coupling the BEOL routing of the IC die 204 down to the solder bumps on the interposer bottom, as shown in more detail in subsequent figures.

Thus, FIG. 2 illustrates an example of an assembly with an organic interposer 202 and a fanout routing die 201 that is embedded in the interposer 202. The fanout routing die 201 shown in FIG. 2 occupies a relatively large area (e.g., area in the x-y plane as shown in FIG. 2, where the y-axis is going into and coming out of the page). A large fanout routing die may provide greater flexibility in routing, but may be prohibitively expensive for some use cases. In some examples, a smaller fanout routing die may provide high-density routing at a lower cost.

FIG. 3 illustrates a cross-sectional side view of an example of a microelectronic assembly 300 including an organic interposer with a fanout routing die, in which a smaller fanout routing die is used to redistribute a high-density bump array on another die to an interconnect pad pattern which is routable on the interposer RDL layers. In the example illustrated in FIG. 3, the tighter pitch and wider pitch contacts are on the same side (e.g., top side) of the fanout routing die 302. Although not shown to scale, the conductive contacts 226-2 may have about the same pitch 233 as the conductive contacts 226-1. For example, the fanout routing die 301 has a first side 337 (e.g., bottom side) and a second side 339 (e.g., top side) opposite the first side 337, and the conductive contacts 226-3 with the narrower pitch 235 and the conductive contacts 226-2 with the wider pitch 233 are on the side 339 (e.g., both the conductive contacts 226-2 and the conductive contacts 226-3 are on the top side of the fanout routing die 301). Although FIG. 4 illustrates the pitch of the conductive contacts 226-2 and the pitch 233 of the conductive contacts 226-1 as being the same, in some examples, the pitch of the conductive contacts 226-2 may be different from the pitch 233. For example, the pitch of the conductive contacts 226-2 may be in between the pitch 233 and the pitch 235 (e.g., smaller than the pitch 233 and greater than the pitch 235). Therefore, the conductive contacts 226-2 are coplanar with the conductive contacts 226-3. Like in FIG. 2, the conductive contacts 226-3 in the assembly 300 of FIG. 3 are coupled with the IC die 204 with a via stack (e.g., the conductive interconnects 231-2) through RDLs 321. However, the assembly 300 of FIG. 3 differs from the assembly 200 of FIG. 2 in that the wider pitch contacts 226-2 on the side 339 of the fanout routing die 301 are coupled with conductive interconnects 231-3 in the RDLs 321. The conductive interconnects 231-3 are coupled with conductive vias 231-4 through the molding compound 222, and the conductive vias 231-4 are coupled with the conductive vias 231-1. Thus, the solder joints 241-1 between the fanout routing die 201 and the bottom of the interposer 202 of FIG. 2 are absent in the assembly 300 of FIG. 3. Instead, there is an electrical path between the conductive contacts 226-2 and the conductive contacts 226-1 through the conductive interconnects 231-3 in the RDLs 321, the conductive vias 231-4, and the conductive vias 231-1.

FIG. 4 illustrates a cross-sectional side view of another example of a microelectronic assembly 400 including an organic interposer with a fanout routing die. In the example illustrated in FIG. 4, the fanout routing die 401 is not embedded between RDLs 421 of the organic interposer 402, but instead is coplanar with the IC die 204. As illustrated in FIG. 4, the RDLs 421 are between the fanout routing die 401 and the conductive contacts 226-1 at the bottom of the interposer 402. In one such example, both the tighter pitch contacts 226-3 and the wider pitch contacts 226-2 are on the same side (e.g., the bottom side) of the fanout routing die 401. For example, the fanout routing die 401 has a first side 437 (e.g., a bottom side) and a second side 439 (e.g., a top side) opposite the first side 437 (where the first side 437 is facing the interposer 402), and the first side includes both the conductive contacts 226-2 and the conductive contacts 226-3 (e.g., both the conductive contacts 226-2 and the conductive contacts 226-3 are on the bottom side of the fanout routing die 401).

In the example illustrated in FIG. 4, the assembly 400 includes an electrical path between the IC die 204 and the conductive bumps 228 at the bottom of the interposer 402. For example, there is an electrical path from the fanout routing die 401 through solder joints 441-1 and 441-2 (e.g., through the conductive contacts 226-6, conductive bumps 228, conductive contacts 226-5), through the conductive interconnects 431-2 in the RDLs 421, through conductive interconnects in the fanout routing die 401, through solder joints 441-1, through the conductive interconnects 431-1 in the RDLs 421, and through the conductive contacts 226-1. In one example, the conductive contacts 226-2 are coupled with the conductive contacts 226-1 with via stacks (e.g., the conductive interconnects 431-1) in the RDLs.

Thus, FIG. 4 illustrates an example of an assembly 400 on top of an organic interposer 402. In some examples, products optimized for die-to-die (D2D) interconnects of the coarser routing design rules of organic dielectric RDL interposers could have a requirement to fanout to IP blocks with a smaller bump pitch and/or higher bump row depth. In one such example, a fanout routing die on top of the interposer (e.g., replacing a dummy die used to fill the interposer between the dies) can provide local routing density, e.g., for the rerouting of crossing signal traces between a hard IP block bump pattern and assignment to the bump-out on the bottom of the interposer without increasing the RDL layer count. Thus, in some examples in which a fanout routing die is disposed over an organic interposer, a dummy die may be absent from the assembly 400.

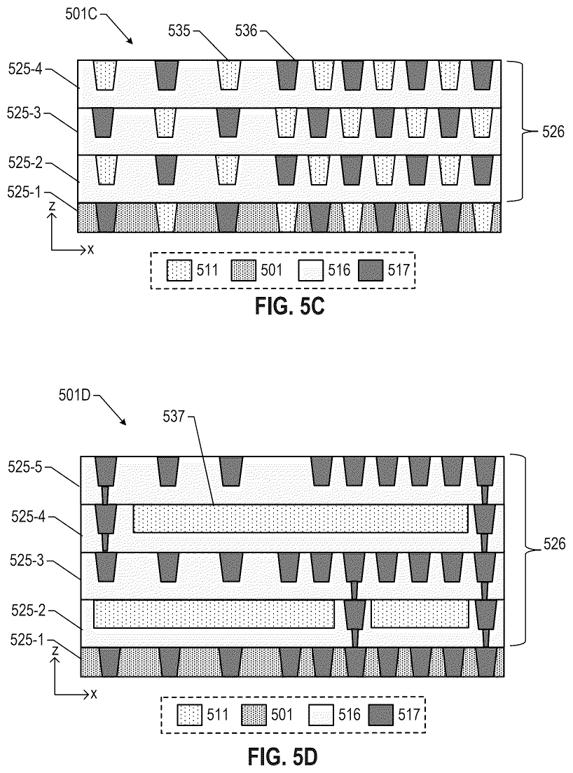

FIGS. 5A-5D illustrate cross-sectional side views of examples of fanout routing dies that may be integrated with organic interposers, according to some embodiments of the present disclosure. In some examples, the fanout routing dies are passive dies (e.g., dies lacking active components such as transistors). Thus, in some examples, the fanout routing dies may be referred to as passive dies or interconnect dies. The fanout routing dies shown in FIGS. 5A-5D include BEOL layers 526 over a substrate 501, where the BEOL layers 526 and substrate 501 may include conductive interconnects (e.g., conductive lines and/or vias) including a conductive material 517. Layers including conductive interconnects may be referred to as interconnect layers. In the example illustrated in FIGS. 5A-5C, the fanout routing dies include four interconnect layers 525-1, 525-2, 525-3, and 525-4. However, in other examples, a fanout routing die may include fewer than four interconnect layers (e.g., two or three interconnect layers) or more than four interconnect layers (e.g., five, six, or another number of interconnect layers greater than four). In one such example, the substrate 501 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate 501 may be non-crystalline. In some examples, the substrate 501 may be or include a layer of glass. In other examples, the substrate 501 may be absent (e.g., removed with polish/etch processes).

In one example, each of the interconnect layers 525-1, 525-2, 525-3, and 525-4 includes a plurality of interconnects electrically coupled to (e.g., in electrically conductive contact with at least portions of) a conductive contact of an interposer and/or IC die. Various interconnect layers 525-1, 525-2, 525-3, and 525-4 may be/include one or more metal layers of a metallization stack. In one example, each of the interconnect layers 525-1, 525-2, 525-3, and 525-4 may include vias and lines/trenches. For example, a metal layer of the interconnect layers 525-4 of FIG. 5A includes a via portion 528b and a line or trench/interconnect portion 528a. The trench portion 528a of a metal layer is configured for transferring signals and power along electrically conductive (e.g., metal) lines (also sometimes referred to as “trenches”) extending in the x-y plane (e.g., in the x or y directions), while the via portion 528b of a metal layer is configured for transferring signals and power through electrically conductive vias extending in the z-direction, e.g., to any of the adjacent metal layers above or below. The width and pitch of conductive interconnects in the interconnect layers 525-1, 525-2, 525-3, and 525-4 may be about the same, may vary in different ones of the interconnect layers 525-1, 525-2, 525-3, and 525-4, and/or may vary within a given interconnect layer. For example, the conductive interconnects may have substantially the same width and pitch in all of the interconnect layers 525-1, 525-2, 525-3, and 525-4. In other examples, one or more of the interconnect layers 525-1, 525-2, 525-3, and 525-4 may have conductive interconnects with a larger width and pitch than other ones of the interconnect layers 525-1, 525-2, 525-3, and 525-4. In some examples, a given one of the interconnect layers 525-1, 525-2, 525-3, and 525-4 may have some conductive interconnects with a first pitch, and other conductive interconnects with a second, different pitch.

Accordingly, in one example, vias connect metal structures (e.g., metal lines or vias) from one layer to metal structures of an adjacent layer. While referred to as “metal” layers, various layers of the interconnect layers 525-1, 525-2, 525-3, and 525-4 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD) 516. The insulating medium may include any suitable ILD materials such as silicon oxide, carbon-doped silicon oxide, silicon carbide, silicon nitride, aluminum oxide, and/or silicon oxynitride. In some embodiments, the dielectric material 516 disposed between the interconnect structures in different ones of the interconnect layers may have different compositions; in other embodiments, the composition of the dielectric material 516 between different interconnect layers may be the same. In some examples, the dielectric material 516 may have a different material composition than the dielectric material in the RDLs of the interposer with which the fanout routing die is integrated. For example, the RDLs of an interposer may include an organic dielectric material that is not silicon-based (e.g., a dielectric material that lacks silicon, or in which silicon is substantially absent), and the ILD 516 of the fanout routing die may include a dielectric material that includes silicon.

Turning to FIG. 5A, the fanout routing die 501A depicted in FIG. 5A includes four layers (e.g., three BEOL layers 526 over a substrate 501), where the layers include conductive lines extending in the same direction (e.g., parallel to one another). Thus, in FIG. 5A, conductive lines in each of the interconnect layers 525-1, 525-2, 525-3, and 525-4 include conductive lines 528a are substantially parallel with one another. For example, the conductive lines 528a in both the interconnect layer 525-3 and the immediately adjacent interconnect layer 525-4 extend along the y-axis, where the y-axis is going into and coming out of the page in FIG. 5A. In the example illustrated in FIG. 5A, some of the conductive interconnects 524 have a narrower pitch, and other conductive interconnects 522 have a wider pitch.

In other examples, one or more interconnect layers of a fanout routing die may include conductive lines that are orthogonal to conductive lines in another layer of the fanout routing die. For example, FIG. 5B illustrates a fanout routing die 501B with four layers (e.g., three BEOL layers 526 over a substrate 501), in which one of the BEOL layers 526 (specifically, the interconnect layer 525-3) includes conductive lines that extend in a different direction (e.g., orthogonally) to conductive lines in other layers of the BEOL layers 526 (e.g., the interconnect layers 525-1, 525-2, and 525-4). Also, FIG. 5B illustrates an example in which one of the BEOL layers has wider conductive lines (e.g., lines with a greater width and pitch relative to other lines in the same layer and/or other lines in other layers). For example, the interconnect layer 525-4 has conductive lines 519 that have a width that is greater than the width of other conductive lines 521, where the width is a dimension of the conductive lines in a plane substantially parallel with the substrate and orthogonal to the length of the lines.

In some examples, a fanout routing die may include shielding material in layers between interconnect layers, in interconnect layers, or both in one or more interconnect layers and between interconnect layers. Lines or planes (e.g., sheets) of a shielding material may form grounding layers or grounding traces, which can be used to improve signal integrity. For example, FIG. 5C illustrates a fanout routing die 501C with four layers (e.g., three BEOL layers 526 over a substrate 501), in which lines 535 including a shielding material 511 may be interspersed or alternating with lines 536 including a conductive material 517 used for signals. In some examples, the shielding material 511 may be the same as, or different from the conductive material 517. For example, both the shielding material 511 and the conductive material may include copper. In another example, the conductive material 517 may be include one conductive material (e.g., copper), and the shielding material 511 may include a different conductive material (e.g., aluminum). Although FIG. 5C depicts the conductive signal lines 536 of the conductive material 517 and the lines 535 of shielding material 511 as having about the same width, in other examples, the lines 535 of the shielding material 511 may have a greater width than the lines 536 used for signals. For example, the lines 536 of the conductive material in a layer (e.g., the layer 525-4 of FIG. 5C) may have a width in a range of about 0.5 to 1 microns, and the lines 535 of the shielding material 511 may have a width that is greater (e.g., in a range of about 1 to 2 microns). Thus, FIG. 5C illustrates an example in which the shielding material 511 may be provided in lines 535 that are substantially parallel with the conductive lines 536 of the conductive material 517.

In other examples, the shielding material 511 may be provided in sheets or planes parallel with the conductive lines. For example, FIG. 5D illustrates a fanout routing die 501D with five layers (e.g., four BEOL layers 526 over a substrate 501), in which sheets 537 of the shielding material 511 are present in some of the interconnect layers 525-1, 525-2, 525-3, 525-4, and 525-5. Specifically, the layers 525-2 and 525-4 include sheets 537 of the shielding material 511, where a sheet 537 of the shielding material 511 has a width that is substantially greater than a width of the conductive lines (e.g., where the width of a sheet in FIG. 5D is a dimension of the sheet in a plane substantially parallel with the substrate 501, e.g., along the x-axis as shown in FIG. 5D). In the example illustrated in FIG. 5D, interconnect layers with conductive interconnects alternate with layers that include one or more sheets 537 of the shielding material 511. For example, the layer 525-2 that includes sheets 537 of the shielding material 511 is between the interconnect layer 525-1 and the interconnect layer 525-3. In one such example, the layer 525-2 may include vias, but may lack metal lines. In other examples, an interconnect layer may include metal lines in addition to sheets of shielding material.

IC assemblies including an organic interposer with a fanout routing die as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of an organic interposer with a fanout routing die as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

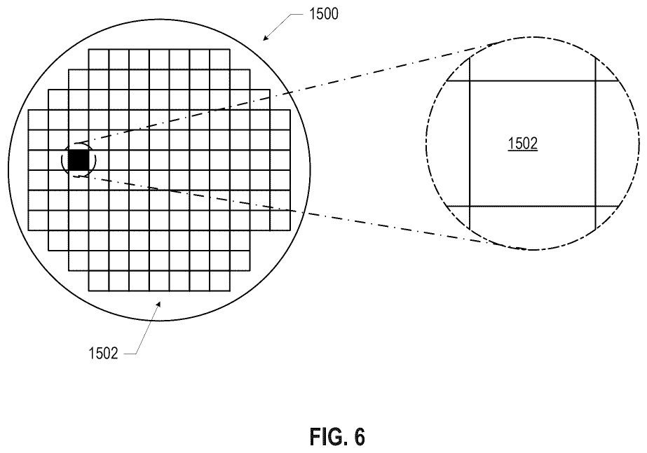

IC assemblies including an organic interposer with a fanout routing die may include or be included in any suitable electronic component or electronic device. FIGS. 6-9 illustrate various examples of apparatuses that may include or be included in an IC assembly including an organic interposer with a fanout routing die disclosed herein.

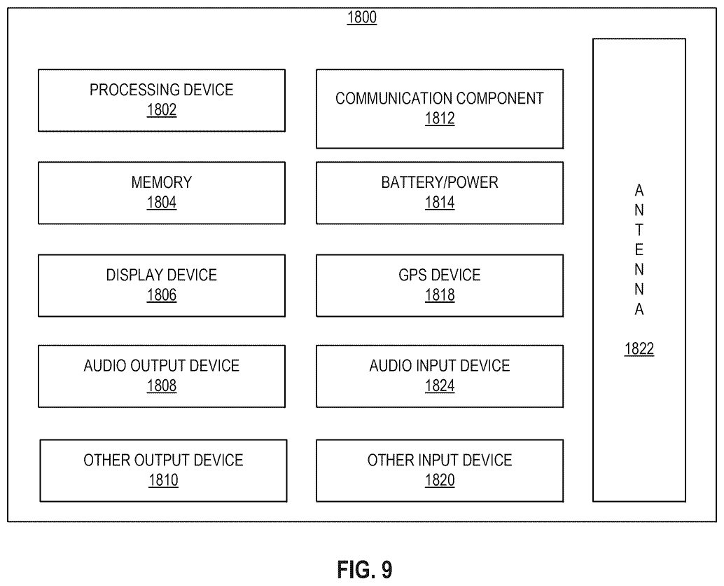

FIG. 6 is a top view of a wafer 1500 and dies 1502 that may include or be included in one or more IC structures or assemblies in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

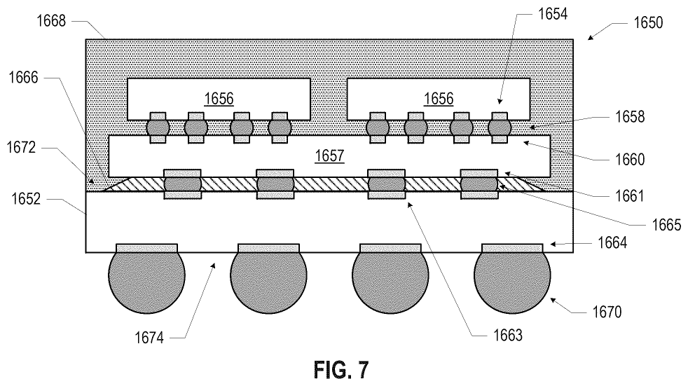

FIG. 7 is a side, cross-sectional view of an example IC package 1650 that may include or be included in a microelectronic assembly in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 7 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 7 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

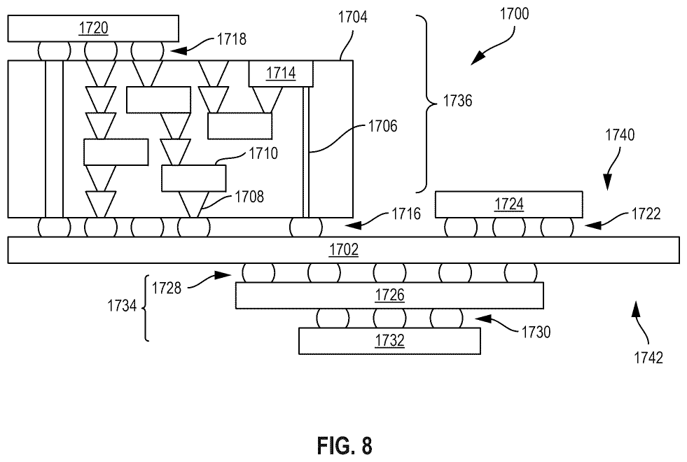

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 7 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 8.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 7 is a flip chip package, other package architectures may be used. For example, the IC package 1650 may be a BGA package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 7, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 8 is a side, cross-sectional view of an IC device assembly 1700 that may include one or more IC packages or other electronic components (e.g., a die) including an organic interposer with a fanout routing die in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 7 (e.g., may include one or more IC structures in accordance with embodiments described herein).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 6), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 8, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example electrical device 1800 that may include or be included in a microelectronic assembly with an organic interposer with a fanout routing die in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides a microelectronic assembly, including an interposer including one or more RDLs, where: the interposer has a first side and a second side opposite the first side, and the first side includes first conductive contacts (e.g., pads) with a first pitch; and an interconnect die (e.g., fanout routing die) including one or more interconnect layers, second conductive contacts with the first pitch coupled with the first conductive contacts, and third conductive contacts with a second pitch that is smaller than the first pitch, where one of the third conductive contacts is coupled with a conductive interconnect in one or more of the RDLs.

Example 2 provides the microelectronic assembly of example 1, where: the interconnect die is between the RDLs and the first conductive contacts (e.g., the fanout routing die is embedded).

Example 3 provides the microelectronic assembly of any one of examples 1-2, where the first side is a first interposer side and the second side is a second interposer side, and where: the interconnect die has a first interconnect die side and a second interconnect die side opposite the first interconnect die side, the first interconnect die side is facing the first interposer side, the first interconnect die side includes the second conductive contacts, and the second interconnect die side includes the third conductive contacts (e.g., the tighter pitch contacts are on the top side of the fanout routing die and the wider pitch contacts are on the bottom side of the fanout routing die).

Example 4 provides the microelectronic assembly of example 3, further including a dielectric material (e.g., underfill) between the first interconnect die side and the first interposer side; and fourth conductive contacts between the first conductive contacts and the second conductive contacts (e.g., there are contacts that connect the fanout routing die with the pads at the bottom of the interposer), where the dielectric material is coplanar with the second conductive contacts and the fourth conductive contacts.

Example 5 provides the microelectronic assembly of example 4, further including a solder joint between one of the second conductive contacts and one of the fourth conductive contacts; and a conductive via between the one of the fourth conductive contacts and one of the first conductive contacts.

Example 6 provides the microelectronic assembly of any one of examples 1-2, where: the second conductive contacts are coplanar with the third conductive contacts.

Example 7 provides the microelectronic assembly of example 6, where the conductive interconnect is a first conductive interconnect, and where the microelectronic assembly further includes a second conductive interconnect in one or more of the RDLs, where the second conductive interconnect is coupled with one of the second conductive contacts.

Example 8 provides the microelectronic assembly of any one of examples 6-7, where the first side is a first interposer side and the second side is a second interposer side, and where: the interconnect die has a first interconnect die side and a second interconnect die side opposite the first interconnect die side, the first interconnect die side is facing the first interposer side, and the second interconnect die side includes the second conductive contacts and the third conductive contacts (e.g., both the tight pitch and wide contacts are on the top side of the fanout routing die facing the IC dies).

Example 9 provides the microelectronic assembly of any one of examples 6-8, further including a dielectric material (e.g., molding compound) over and around the interconnect die; and a conductive via through the dielectric material between one of the first conductive contacts and a second conductive interconnect in one or more of the RDLs, where the second conductive interconnect is coupled with one of the second conductive contacts.

Example 10 provides the microelectronic assembly of example 9, where the dielectric material is a first dielectric material, and where the microelectronic assembly further includes a second dielectric material between the interconnect die and the first side of the interposer.

Example 11 provides the microelectronic assembly of any one of examples 6-7, where the first side is a first interposer side and the second side is a second interposer side, and where: the interconnect die has a first interconnect die side and a second interconnect die side opposite the first interconnect die side, the first interconnect die side is facing the interposer, and the first interconnect die side includes the second conductive contacts and the third conductive contacts (e.g., both the tight pitch and wide contacts are on the bottom side of the fanout routing die facing the interposer).

Example 12 provides the microelectronic assembly of example 11, where: the RDLs are between the interconnect die and the first conductive contacts.

Example 13 provides the microelectronic assembly of any one of examples 1-12, where: conductive lines in each of the one or more interconnect layers that include the conductive lines are substantially parallel with one another.

Example 14 provides the microelectronic assembly of any one of examples 1-12, where: at least one of the one or more interconnect layers includes a shielding element, where the shielding element includes a conductive line or plane that is substantially parallel with conductive lines in the one or more interconnect layers.

Example 15 provides a microelectronic assembly, including an organic interposer with a first side and a second side opposite the first side, where the organic interposer includes first conductive contacts (e.g., pads) with a first pitch on the first side; an IC die (e.g., chiplet) coupled with the second side of the organic interposer, where the IC die includes second conductive contacts (e.g., pads) with a second pitch that is smaller than the first pitch; and an interconnect die (e.g., fanout routing die) including one or more interconnect layers, third conductive contacts with the first pitch coupled with the first conductive contacts, fourth conductive contacts with the second pitch coupled with the second conductive contacts, where: a conductive interconnect in the organic interposer is between and coupled with one of the second conductive contacts and one of the fourth conductive contacts.

Example 16 provides the microelectronic assembly of example 15, where: the interconnect die is coplanar with the IC die.

Example 17 provides the microelectronic assembly of example 15, where: the organic interposer includes one or more RDLs between the interconnect die and the IC die.

Example 18 provides the microelectronic assembly of any one of examples 15-17, where the IC die is a first IC die, and where the microelectronic assembly further includes a second IC die coplanar with the first IC die and coupled with the second side of the organic interposer, where the second IC die includes fifth conductive contacts with a third pitch that is different from the first pitch and the second pitch.

Example 19 provides a microelectronic assembly, including a substrate (e.g., interposer) including one or more layers with first conductive interconnects in an organic dielectric material, where the substrate has a first side and a second side that is opposite the first side; first conductive contacts on the first side of the substrate, where the first conductive contacts have a first pitch; a die including one or more BEOL layers, where the one or more BEOL layers include second conductive interconnects; second conductive contacts on the die and electrically coupled with the first conductive contacts, where the second conductive contacts have a second pitch, and where the second pitch is about the same as the first pitch; and third conductive contacts on the die coupled with one of the first conductive interconnects, where the third conductive contacts are to couple with a further die, and where the third conductive contacts have a third pitch that is smaller than the first pitch.

Example 20 provides the microelectronic assembly of example 19, where: the die is embedded in the substrate between the layers of the organic dielectric material.

Example 21 provides the microelectronic assembly of any one of examples 19-20, where: the second conductive contacts are on a side of the die facing the first conductive contacts.

Example 22 provides the microelectronic assembly of any one of examples 19-20, where: the second conductive contacts are on a side of the die facing away from the first conductive contacts.

Example 23 provides the microelectronic assembly of any one of examples 19-22, where: the second conductive contacts and the third conductive contacts are on opposite sides of the die.

Example 24 provides the microelectronic assembly of any one of examples 19-22, where: the second conductive contacts and the third conductive contacts are on a same side of the die.

Example 25 provides the microelectronic assembly of example 19, where: the die is over and bonded with substrate, the second conductive contacts are on a side of the die bonded with the substrate, and the substrate includes a via stack through the one or more layers between one of the first conductive contacts and one of the second conductive contacts.

Example 26 provides the microelectronic assembly of any one of examples 19-25, further including a further die over and bonded with the substrate; and fourth conductive contacts on the further die, where one of the first conductive interconnects is between one of the fourth conductive contacts and one of the third conductive contacts.

Example 27 provides the microelectronic assembly according to any one of examples 1-26, where the microelectronic assembly includes or is a part of a central processing unit.

Example 28 provides the microelectronic assembly according to any one of examples 1-27, where the microelectronic assembly includes or is a part of a memory device.

Example 29 provides the microelectronic assembly according to any one of examples 1-28, where the microelectronic assembly includes or is a part of a logic circuit.

Example 30 provides the microelectronic assembly according to any one of examples 1-29, where the microelectronic assembly includes or is a part of input/output circuitry.

Example 31 provides the microelectronic assembly according to any one of examples 1-30, where the microelectronic assembly includes or is a part of a field programmable gate array transceiver.

Example 32 provides the microelectronic assembly according to any one of examples 1-31, where the microelectronic assembly includes or is a part of a field programmable gate array logic.

Example 33 provides the microelectronic assembly according to any one of examples 1-32, where the microelectronic assembly includes or is a part of a power delivery circuitry.

Example 34 provides an IC package that includes a microelectronic assembly according to any one of examples 1-33.

Example 35 provides the IC package according to example 34, further including a further IC component coupled to the microelectronic assembly.

Example 36 provides the IC package according to example 35, where the further IC component includes a package substrate.

Example 37 provides the IC package according to example 35, where the further IC component includes an interposer.

Example 38 provides the IC package according to example 35, where the further IC component includes a further assembly or die.

Example 39 provides a computing device that includes a carrier substrate and an assembly coupled to the carrier substrate, where the assembly is an assembly according to any one of examples 1-33, or the assembly is included in the IC package according to any one of examples 34-38.

Example 40 provides the computing device according to example 39, where the computing device is a wearable or handheld computing device.

Example 41 provides the computing device according to examples 39 or 40, where the computing device further includes one or more communication chips.

Example 42 provides the computing device according to any one of examples 39-41, where the computing device further includes an antenna.

Example 43 provides the computing device according to any one of examples 39-42, where the carrier substrate is a motherboard.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly, comprising:
an interposer comprising one or more redistribution layers (RDLs), wherein:
the interposer has a first side and a second side opposite the first side, and
the first side comprises first conductive contacts with a first pitch; and
an interconnect die comprising:
one or more interconnect layers,
second conductive contacts with the first pitch coupled with the first conductive contacts, and
third conductive contacts with a second pitch that is smaller than the first pitch, wherein one of the third conductive contacts is coupled with a conductive interconnect in one or more of the RDLs.

2. The microelectronic assembly of claim 1, wherein:
the interconnect die is between the RDLs and the first conductive.

3. The microelectronic assembly of claim 1, wherein the first side is a first interposer side and the second side is a second interposer side, and wherein:
the interconnect die has a first interconnect die side and a second interconnect die side opposite the first interconnect die side,
the first interconnect die side is facing the first interposer side,
the first interconnect die side comprises the second conductive contacts, and
the second interconnect die side comprises the third conductive contacts.

4. The microelectronic assembly of claim 3, further comprising:
a dielectric material between the first interconnect die side and the first interposer side; and
fourth conductive contacts between the first conductive contacts and the second conductive contacts, wherein the dielectric material is coplanar with the second conductive contacts and the fourth conductive contacts.

5. The microelectronic assembly of claim 4, further comprising:
a solder joint between one of the second conductive contacts and one of the fourth conductive contacts; and
a conductive via between the one of the fourth conductive contacts and one of the first conductive contacts.

6. The microelectronic assembly of claim 1, wherein:
the second conductive contacts are coplanar with the third conductive contacts.

7. The microelectronic assembly of claim 6, wherein the conductive interconnect is a first conductive interconnect, and wherein the microelectronic assembly further comprises:
a second conductive interconnect in one or more of the RDLs, wherein the second conductive interconnect is coupled with one of the second conductive contacts.

8. The microelectronic assembly of claim 6, wherein the first side is a first interposer side and the second side is a second interposer side, and wherein:
the interconnect die has a first interconnect die side and a second interconnect die side opposite the first interconnect die side,
the first interconnect die side is facing the first interposer side, and
the second interconnect die side comprises the second conductive contacts and the third conductive contacts.

9. The microelectronic assembly of claim 6, further comprising:
a dielectric material over and around the interconnect die; and
a conductive via through the dielectric material between one of the first conductive contacts and a second conductive interconnect in one or more of the RDLs, wherein the second conductive interconnect is coupled with one of the second conductive contacts.

10. The microelectronic assembly of claim 9, wherein the dielectric material is a first dielectric material, and wherein the microelectronic assembly further comprises:
a second dielectric material between the interconnect die and the first side of the interposer.

11. The microelectronic assembly of claim 6, wherein the first side is a first interposer side and the second side is a second interposer side, and wherein:
the interconnect die has a first interconnect die side and a second interconnect die side opposite the first interconnect die side,
the first interconnect die side is facing the interposer, and
the first interconnect die side comprises the second conductive contacts and the third conductive contacts.

12. The microelectronic assembly of claim 11, wherein:
the RDLs are between the interconnect die and the first conductive contacts.

13. The microelectronic assembly of claim 1, wherein:
conductive lines in each of the two or more interconnect layers that comprise the conductive lines are substantially parallel with one another.

14. The microelectronic assembly of claim 1, wherein:
at least one of the one or more interconnect layers comprises a shielding element, wherein the shielding element comprises a conductive line or plane that is substantially parallel with conductive lines in the one or more interconnect layers.

15. A microelectronic assembly, comprising:
an organic interposer with a first side and a second side opposite the first side, wherein the organic interposer comprises first conductive contacts with a first pitch on the first side;
an integrated circuit (IC) die coupled with the second side of the organic interposer, wherein the IC die comprises second conductive contacts with a second pitch that is smaller than the first pitch; and
an interconnect die comprising:
one or more interconnect layers,
third conductive contacts with the first pitch coupled with the first conductive contacts,
fourth conductive contacts with the second pitch coupled with the second conductive contacts, wherein:
a conductive interconnect in the organic interposer is between and coupled with one of the second conductive contacts and one of the fourth conductive contacts.

16. The microelectronic assembly of claim 15, wherein:
the interconnect die is coplanar with the IC die.

17. The microelectronic assembly of claim 15, wherein:
the organic interposer comprises one or more redistribution layers (RDLs) between the interconnect die and the IC die.

18. The microelectronic assembly of claim 15, wherein the IC die is a first IC die, and wherein the microelectronic assembly further comprises:
a second IC die coplanar with the first IC die and coupled with the second side of the organic interposer, wherein the second IC die comprises fifth conductive contacts with a third pitch that is different from the first pitch and the second pitch.

19. A microelectronic assembly, comprising:
a substrate comprising one or more layers with first conductive interconnects in an organic dielectric material, wherein the substrate has a first side and a second side that is opposite the first side;
first conductive contacts on the first side of the substrate, wherein the first conductive contacts have a first pitch;
a die comprising two or more back end of line (BEOL) layers, wherein the two or more BEOL layers comprise second conductive interconnects;
second conductive contacts on the die and electrically coupled with the first conductive contacts, wherein the second conductive contacts have a second pitch, and wherein the second pitch is about the same as the first pitch; and
third conductive contacts on the die coupled with one of the first conductive interconnects, wherein the third conductive contacts are to couple with a further die, and wherein the third conductive contacts have a third pitch that is smaller than the first pitch.

20. The microelectronic assembly of claim 19, wherein:
the die is embedded in the substrate between the layers of the organic dielectric material.
